(19) United States
(12) Patent Application Publication
(10) Pub. No.: US 2021/0357050 A1
(43) Pub. Date: Nov. 18, 2021

(54) TOUCH DISPLAY SUBSTRATE, MANUFACTURING METHOD, TOUCH DISPLAY DEVICE AND DRIVING METHOD

(71) Applicant: BOE TECHNOLOGY GROUP CO., LTD., Beijing (CN)

(72) Inventor: Haixu LI, Beijing (CN)

(73) Assignee: BOE TECHNOLOGY GROUP CO., LTD., Beijing (CN)

(21) Appl. No.: 16/346,490

(22) PCT Filed: Sep. 5, 2018
(86) PCT No.: PCT/CN2018/104129

§ 371 Date: Apr. 30, 2019

(30) Foreign Application Priority Data
Feb. 1, 2018 (CN) 201810102956.0

(51) Int. Cl. G06F 3/041; G02F 1/1333; H01L 27/32; H01L 51/56; G06F 3/044

(52) U.S. Cl. CPC G06F 3/0412; G02F 1/13338; H01L 27/323; G02F 1/133512; G06F 3/0447; G06F 3/04166; H01L 51/56

(57) ABSTRACT

A touch display substrate, a manufacturing method, a touch display device and a driving method are provided. The touch display substrate includes: a base substrate, a first touch-control electrode, a second touch-control electrode and a separation pattern. The base substrate includes multiple pixel units, each pixel unit is provided with a first electrode and a second electrode insulated from each other. The separation pattern is arranged between two adjacent pixel units and is made of an insulating material. The first touch-control electrode is located at a side of the separation pattern close to the base substrate. The second touch-control electrode is located at a side of the separation pattern away from the base substrate. The first touch-control electrode is arranged in an identical layer to the first electrode, and the second touch-control electrode is arranged in an identical layer to the second electrode.

### CROSS-REFERENCE TO RELATED APPLICATION

This application claims a priority to Chinese Patent Application No. 201810102956.0 filed on Feb. 1, 2018, the disclosure of which is incorporated in its entirety by reference herein.

### TECHNICAL FIELD

The present disclosure relates to the field of touch display technology, for example, to a touch display substrate, a manufacturing method, a touch display device and a driving method.

### BACKGROUND

In related technology, a touch recognition structure in a touch display product is arranged in an out of cell manner, that is, the touch recognition structure is further arranged outside a display panel to realize touch recognition function. The out of cell arrangement, which increases product thickness and results in low integration level, does not confirm with a current developing trend of ultrathin display products.

### SUMMARY

A touch display substrate is provided, including: a base substrate, a first touch-control electrode, a second touch-control electrode and a separation pattern. The base substrate includes multiple pixel units, each pixel unit comprises a first electrode and a second electrode insulated from each other; the separation pattern is arranged between two adjacent pixel units and is made of an insulating material; the first touch-control electrode is arranged at a side of the separation pattern close to the base substrate; the second touch-control electrode is arranged at a side of the separation pattern away from the base substrate; the first touch-control electrode and the first electrode are arranged in a same layer; and the second touch-control electrode and the second electrode are arranged in a same layer.

In some embodiments, a distance between the first electrode and the first touch-control electrode adjacent to each other ranges from 5 μm to 15 μm.

In some embodiments, the first electrode and the first touch-control electrode are made of an identical material.

In some embodiments, the second electrode and the second touch-control electrode are made of an identical material.

In some embodiments, the first electrode and the first touch-control electrode are made of an identical material, and the second electrode and the second touch-control electrode are made of an identical material.

In some embodiments, the touch display substrate further includes a thin film transistor formed on the base substrate, where a drain electrode of the thin film transistor is connected to the first electrode.

In some embodiments, the touch display substrate further includes an organic light-emitting layer arranged between the first electrode and the second electrode.

In some embodiments, the separation pattern is a black matrix or a pixel defining layer.

A manufacturing method for a touch display substrate is provided, including: forming multiple pixel units on a base substrate, where each pixel unit includes a first electrode and a second electrode insulated from each other; forming a separation pattern between two adjacent pixel units, where the separation pattern is made of an insulating material; forming a first touch-control electrode on a side of the separation pattern close to the base substrate; and forming a second touch-control electrode on a side of the separation pattern away from the base substrate. The first touch-control electrode and the first electrode are arranged in a same layer, and the second touch-control electrode and the second electrode are arranged in a same layer.

In some embodiments, the manufacturing method includes: forming a conductive pattern on the base substrate before forming the multiple pixel units on the base substrate; forming a first insulating layer covering the conductive pattern; and forming a first via-hole in the first insulating layer to expose the conductive pattern. The forming the multiple pixel units on the base substrate and the forming the first touch-control electrode on the side of the separation pattern close to the base substrate include: forming the first electrode and the first touch-control electrode on the first insulating layer through one patterning process, where the first touch-control electrode is connected to the conductive pattern via the first via-hole. The manufacturing method further includes: forming a second insulating layer covering the first electrode and the first touch-control electrode, after forming the first electrode and the first touch-control electrode on the first insulating layer, where the second insulating layer includes a second via-hole through which the first electrode exposes; and forming an organic light-emitting layer, where the organic light-emitting layer is connected to the first electrode via the second via-hole, and an orthographic projection of the separation pattern onto the base substrate at least covers an orthographic projection of the first touch-control electrode onto the base substrate. The forming the multiple pixel units on the base substrate and the forming the second touch-control electrode on the side of the separation pattern away from the base substrate includes: forming the second electrode and the second touch-control electrode through one patterning process, where an orthographic projection of the second electrode onto the base substrate is within an orthographic projection of the first electrode onto the base substrate, and an orthographic projection of the second touch-control electrode onto the base substrate is within the orthographic projection of the first touch-control electrode onto the base substrate.

A touch display device is provided, including the above-described touch display substrate.

A driving method is provided, applied to the above-described touch display device, including: at a display stage, applying display signals for displaying an image to the first electrode and the second electrode of each pixel unit respectively; and at a touch recognition stage, applying touch-control signals for recognizing a touch operation to the first touch-control electrode and the second touch-control electrode respectively.

### BRIEF DESCRIPTION OF THE DRAWINGS

FIG. 1 is a schematic structural diagram of a touch display substrate according to some embodiments;

FIG. 2 is a schematic structural diagram of a touch display substrate according to some other embodiments;

FIG. 3 is a schematic structural diagram of a touch display substrate according to some other embodiments;

FIG. 4 is a flow chart of a manufacturing method for a touch display substrate according to some embodiments;

FIG. 5 is a flow chart of a driving method according to some embodiments; and

FIG. 6 is a schematic timing diagram of touch-control signal application in a driving method according to some embodiments.

### DETAILED DESCRIPTION

In related technology, a touch display product having a touch recognition structure arranged in an out of cell manner is thick and has a low integration level of components.

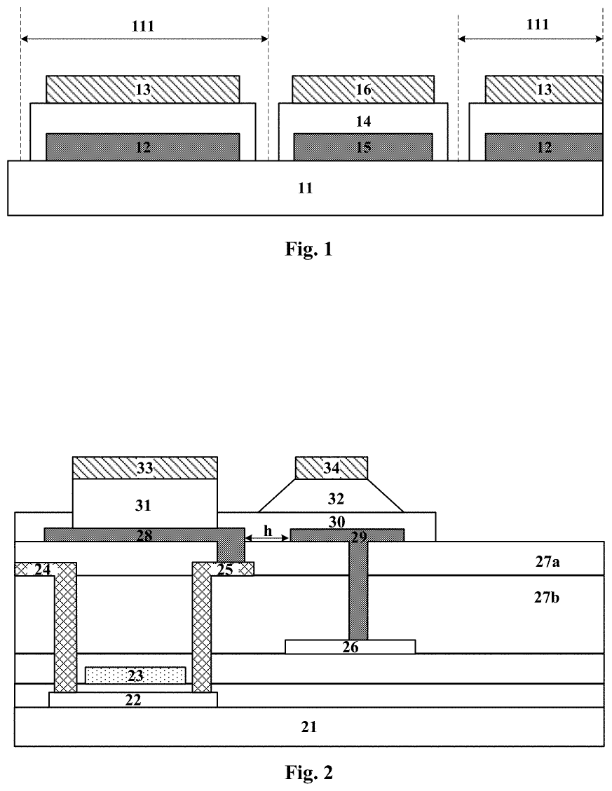

A touch display substrate is provided in some embodiments. As shown in FIG. 1, the touch display substrate includes a base substrate 11, a first touch-control electrode 15, a second touch-control electrode 16 and a separation pattern 14.

The base substrate 11 includes multiple pixel units 111 (Pixel). Each pixel unit 111 is provided with a first electrode 12 and a second electrode 13 insulated from each other.

Exemplarily, in a case of applying the touch display substrate in the foregoing embodiments to a liquid crystal display, the first electrode 12 and the second electrode 13 are respectively a common electrode and a pixel electrode. Exemplarily, in a case of applying the touch display substrate in the foregoing embodiments to an organic light-emitting diode (OLED) display, the first electrode 12 and the second electrode 13 are respectively an anode and a cathode. The separation pattern 14 is arranged between two adjacent pixel units 111. The separation pattern is made of an insulating material, and at least can separate the two adjacent pixel units 111 or raise a layer.

Exemplarily, in a case of applying the touch display substrate in the foregoing embodiments to a liquid crystal display, the separation pattern 14 is a black matrix of the liquid crystal display. Exemplarily, in a case of applying the touch display substrate in the foregoing embodiments to an OLED display, the separation pattern 14 is a pixel defining layer of the OLED display.

In some embodiments, the touch display substrate further includes a first touch-control electrode 15 and a second touch-control electrode 16. The first touch-control electrode 15 is located at a side of the separation pattern 14 close to the base substrate 11. The second touch-control electrode 16 is located at a side of the separation pattern 14 away from the base substrate 11.

The first touch-control electrode 15 is arranged in an identical layer to the first electrode 12. The second touch-control electrode 16 is arranged in an identical layer to the second electrode 13. The first touch-control electrode 15 and the second touch-control electrode 16 form a mutual-capacitive touch recognition structure. When a press occurs, a distance between the first touch-control electrode 15 and the second touch-control electrode 16 is changed and a capacitance formed therebetween is changed accordingly.

In some embodiments, touch signals are applied to the first touch-control electrode 15 and the second touch-control electrode 16 and a touch operation may be recognized by detecting a change of the capacitance.

In the above embodiments, the mutual-capacitive touch recognition structure is arranged between the pixel units, the first touch-control electrode in the touch recognition structure is arranged in an identical layer to the first electrode in the pixel unit, the second touch-control electrode in the touch recognition structure is arranged in an identical layer to the second electrode in the pixel unit, such that a display function and a touch-control function are integrated to a same substrate. Compared with the touch display device including the touch recognition structure arranged in an out of cell manner in related technology, the touch recognition structure of the touch display substrate in the above embodiments occupies an in-cell space of a display module, thereby reducing a thickness of the display product and making the display product thinner.

In some embodiments, the touch display substrate is applied to an OLED display and a structure of the touch display substrate is shown in FIG. 2. The touch display substrate includes a base substrate 21, a thin film transistor formed on the base substrate 21, a conductive pattern 26, a first insulating layer 27a and 27b, a first electrode 28, a first touch-control electrode 29, a pixel defining layer 30, an organic light-emitting layer 31, a spacer 32 (i.e., the separation pattern), a second electrode 33 and a second touch-control electrode 34.

The thin film transistor includes an active layer 22, a gate electrode 23, a source electrode 24 and a drain electrode 25. In some embodiments, a top-gate thin film transistor or a bottom-gate thin film transistor is applied to the touch display substrate.

The conductive pattern 26 transmits a touch-control signal to the first touch-control electrode 29. In some embodiments, the conductive pattern 26 receives different signals in a display stage and a touch-control stage. In some embodiments, the conductive pattern 26 is dedicated for transmitting a signal to the first touch-control electrode 29.

In some embodiments, the first insulating layer 27a and 27b covering the conductive pattern 26 has a single layer structure. In some embodiments, the first insulating layer 27a and 27b covering the conductive pattern 26 has a multilayer structure.

The first electrode 28 and the first touch-control electrode 29 are formed on the first insulating layer 27a and 27b. The first touch-control electrode 29 is connected to the conductive pattern 26 via a via-hole in the first insulating layer 27, thereby being driven by a signal on the conductive pattern 26. The first electrode 28 is connected to the drain electrode 25 of the thin film transistor via a via-hole in the first insulating layer 27, such that the thin film transistor serves as a switch that applies a signal to the first electrode 28.

In some embodiments, the first electrode 28 and the first touch-control electrode 29 are made of an identical material, such that they may be made through one patterning process and manufacturing cost is reduced.

In some embodiments, to prevent the first electrode 28 applied with the signal from influencing the first touch-control electrode 29, a distance h between the first electrode 28 and the first touch-control electrode 29 adjacent to each other ranges from 5 μm to 15 μm (including 5 μm and 15 μm). The distance refers to a distance between the first electrode 28 and the first touch-control electrode 29 adjacent to each other in a direction parallel with a surface of the base substrate 21.

The pixel defining layer 30 covers the first touch-control electrode 29 and includes a via-hole through which the first electrode 28 exposes.

The organic light-emitting layer 31 is connected to the first electrode 28 through a via-hole in the pixel defining layer 30.

A vertical distance between a surface of the second touch-control electrode 34 away from the base substrate 21 and a surface of the base substrate 21 close to the thin film transistor is h1. A vertical distance between a surface of the second electrode 33 away from the base substrate 21 and the surface of the base substrate 21 close to the thin film transistor is h2. The spacer 32 has a function of layer raising, such that a difference between h1 and h2 may not be too large.

The second electrode 33 is formed on the organic light-emitting layer 31. The second touch-control electrode 34 is formed on the spacer 32.

In some embodiments, the second electrode 33 and the second touch-control electrode 34 are made of an identical material.

Since the second electrode 33 and the second touch-control electrode 34 are made of the identical material, they may be made through one patterning process to reduce the manufacturing cost.

Based on the structure shown in FIG. 2, touch recognition function may be realized by applying touch-control signals to the first touch-control electrode 29 and the second touch-control electrode 34 according to the foregoing embodiments.

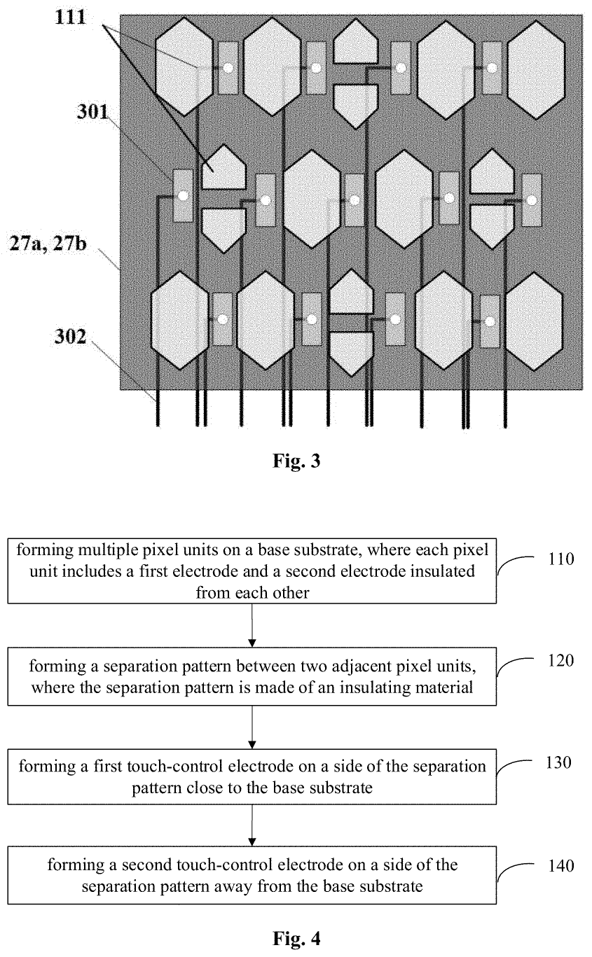

In some embodiments, as shown in FIG. 3, multiple touch recognition structures (each including the first touch-control electrode, the second touch-control electrode and the separation pattern) are provided. The multiple touch recognition structures are arranged in regions 301 between adjacent pixel units 111. The multiple touch recognition structures are arranged in an array. Data lines 302 connected to the first touch-control electrodes 29 in the respective touch recognition structures are arranged in in identical layer to the conductive pattern 26. The data lines 302 penetrate the first insulating layer 27a and 27b and are connected to corresponding first touch-control electrodes 29.

In the exemplary description of the touch display substrate according to the foregoing embodiments, formation of the first electrode and the second electrode is not limited; the conductive patterns insulated from each other are formed between the pixel units of the touch display substrate, and a patterning process for forming the conductive patterns may be used to form the first touch-control electrodes and the second touch-control electrodes.

In some embodiments, as shown in FIG. 4, a manufacturing method for a touch display substrate is provided. The manufacturing method includes steps 110 to 140.

Step 110 includes: forming multiple pixel units on a base substrate, where each pixel unit includes a first electrode and a second electrode insulated from each other.

Step 120 includes: forming a separation pattern between two adjacent pixel units, where the separation pattern is made of an insulating material.

Step 130 includes: forming a first touch-control electrode on a side of the separation pattern close to the base substrate.

Step 140 includes: forming a second touch-control electrode on a side of the separation pattern away from the base substrate.

The first touch-control electrode and the first electrode are arranged in an identical layer. The second touch-control electrode and the second electrode are arranged in an identical layer.

In some embodiments, the above manufacturing method may be used to manufacture the touch display substrate according to the foregoing embodiments.

Taking the touch display substrate in FIG. 2 for example, the manufacturing method may include the followings steps.

In step 1, the conductive pattern 26 is formed on the base substrate 21.

In some embodiments, the base substrate 21 is a glass substrate, a quartz substrate, a silicone substrate, a plastic substrate or a polyimide substrate.

In some embodiments, a metallic layer having a thickness of about 500 to 4000 Å is deposited on the substrate after step 1 with a manner of sputtering or thermal evaporation.

In some embodiments, the metallic layer is made of Cu, Al, Ag, Mo, Cr, Nd, Ni, Mn, Ti, Ta or W, or any alloy of the above metals. The metallic layer may have a single layer structure, or a multilayer structure such as Cu\Mo, Ti\Cu\Ti, Mo\Al\Mo.

A layer of photoresist is applied on the metallic layer and is exposed with a mask to form a photoresist unreserved region and a photoresist reserved region. The photoresist reserved region corresponds to a region where a pattern of the conductive pattern 26 is located. The photoresist unreserved region corresponds to a region except for the pattern.

A developing process is performed, the photoresist in the photoresist unreserved region is completely removed and a thickness of the photoresist in the photoresist reserved region is maintained unchanged.

The metallic layer in the photoresist unreserved region is completely etched via an etching process and remained photoresist is peeled off, to form the pattern of the conductive pattern 26.

In step 2, the first insulating layer 27a and 27b covering the conductive pattern 26 is formed.

In some embodiments, the first insulating layer 27a and 27b having a thickness of 500 to 5000 Å is deposited on the substrate after step 2 with a manner of Plasma Enhanced Chemical Vapor Deposition (PECVD).

In some embodiments, the first insulating layer 27a and 27b may be made of an oxide, a nitride or a nitric oxide, and a corresponding reactant gas may be SiH₄, NH3, N₂ or SiH₂Cl₂, NH₃, N₂.

In step 3, a first via-hole is formed in the first insulating layer 27a and 27b to expose the conductive pattern 26.

In step 4, the first electrode 28 and the first touch-control electrode 29 are formed on the first insulating layer 27a and 27b through one patterning process, where the first touch-control electrode 29 is connected to the conductive pattern 26 via the first via-hole.

In some embodiments, a transparent conductive layer having a thickness of about 300 to 1500 Å is deposited on the base substrate 21 with a manner of sputtering or thermal evaporation. The transparent conductive layer may be made of ITO, IZO or other transparent metallic oxides. A layer of photoresist is applied on the transparent conductive layer and is exposed with a mask to form a photoresist unreserved region and a photoresist reserved region.

The photoresist reserved region corresponds to a region where patterns of the first electrode 28 and the first touch-control electrode 29 are located. The photoresist unreserved region corresponds to a region except for the above patterns. A developing process is performed, the photoresist in the photoresist unreserved region is completely removed and a thickness of the photoresist in the photoresist reserved region is maintained unchanged. A transparent conductive layer film in the photoresist unreserved region is completely etched via an etching process and remained photoresist is peeled off to form the patterns of the first electrode 28 and the first touch-control electrode 29.

In step 5, a second insulating layer 30 covering the first electrode 28 and the first touch-control electrode 29 is formed.

In some embodiments, the second insulating layer 30 is a pixel defining layer and includes a second via-hole through which the first electrode 28 exposes.

In some embodiments, the second insulating layer 30 having a thickness of 500 to 5000 Å is deposited on the substrate after step 2 with a manner of PECVD.

In some embodiments, the second insulating layer 30 may be made of an oxide, a nitride or a nitric oxide and a corresponding reactant gas may be SiH₄, NH₃, N₂ or SiH₂Cl₂, NH₃, N₂.

In step 6, the organic light-emitting layer 31 and the separation pattern 32 are formed.

The organic light-emitting layer 31 is connected to the first electrode 28 via the second via-hole. An orthographic projection of the separation pattern 32 onto the base substrate 21 at least covers an orthographic projection of the first touch-control electrode 29 onto the base substrate 21.

In step 7, the second electrode 33 and the second touch-control electrode 34 are formed through one patterning process.

An orthographic projection of the second electrode 33 onto the base substrate 21 is within an orthographic projection of the first electrode 28 onto the base substrate 21. An orthographic projection of the second touch-control electrode 34 onto the base substrate is within the orthographic projection of the first touch-control electrode 29 onto the base substrate 21.

In some embodiments, a transparent conductive layer having a thickness of about 300 to 1500 Å is deposited on the substrate after step 6 with a manner of sputtering or thermal evaporation. The transparent conductive layer may be made of ITO, IZO or other transparent metallic oxides. A layer of photoresist is applied on the transparent conductive layer and is exposed with a mask to form a photoresist unreserved region and a photoresist reserved region.

The photoresist reserved region corresponds to a region where patterns of the second electrode 33 and the second touch-control electrode 34 are located. The photoresist unreserved region corresponds to a region except for the above patterns.

A developing process is performed, the photoresist in the photoresist unreserved region is completely removed and a thickness of the photoresist in the photoresist reserved region is maintained unchanged.

A transparent conductive layer film in the photoresist unreserved region is completely etched via an etching process and remained photoresist is peeled off to form the patterns of the second electrode 33 and the second touch-control electrode 34.

In some embodiments, an encapsulation layer is formed on the substrate after step 7 through an evaporation process, to protect an organic light-emitting element, thereby improving waterproof capability, oxygen resistance and service life of an overall device.

In some embodiments, a thin film transistor is formed based on the above manufacturing method.

A touch display device is provided according to some embodiments, including the touch display substrate according to the foregoing embodiments of the present disclosure.

In the touch display device according to the embodiments, a touch recognition structure is integrated in the touch display substrate, thereby reducing a product thickness and making the display device thinner.

In some embodiments, the touch display device is a display product having a touch-control function, such as a cellphone, a tablet computer or a television.

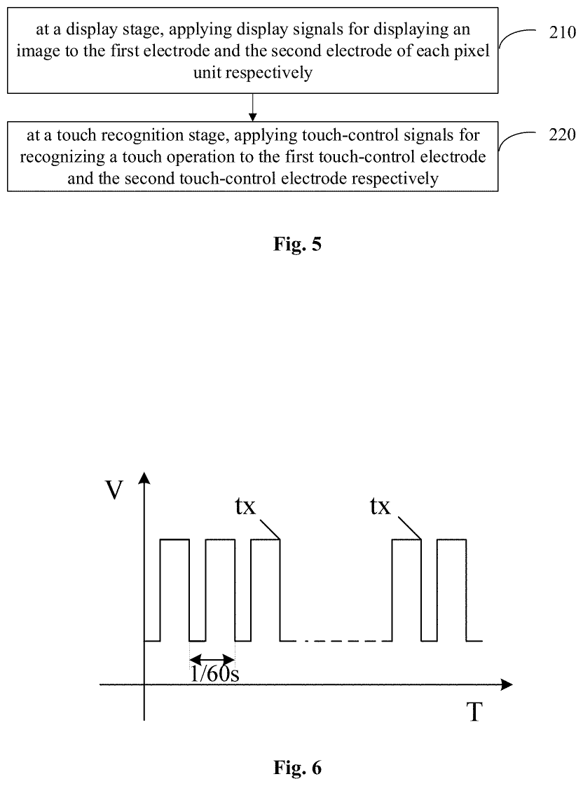

A driving method is provided according to some embodiments, which is applied to the touch display device according to the foregoing embodiments. As shown in FIG. 5, the driving method includes step 210 and step 220.

In step 210, at a display stage, display signals for displaying an image are respectively applied to the first electrode and the second electrode of each pixel unit. For example, the display signals respectively applied to the first electrode and the second electrode of the pixel unit are a data signal and a common voltage signal.

In step 220, at a touch recognition stage, touch-control signals for recognizing a touch operation are respectively applied to the first touch-control electrode and the second touch-control electrode. For example, the touch-control signals respectively applied to the first touch-control electrode and the second touch-control electrode are a touch-control driving signal and a touch-control sensing signal.

Taking cellphones for example, a scanning frequency of a display screen of some cellphones is 60 Hz, the shortest time spent on touching a touch screen once by a hand is generally ¼s, that is, a touch operation of a user can be detected by applying 4 touch-control signals in 1s. In some cellphones, the display signals further serve as the touch-control signals.

In some embodiments, as shown in FIG. 6, a vertical axis indicates voltage and a horizontal axis indicates time. In 1s, signals are applied for 60 periods. Touch-control signals tx may occupy 4 periods and display signals occupy the other 56 periods. In a case that any adjacent touch-control signals tx are spaced by an identical quantity of period(s), a maximum interval between two adjacent touch-control signals is 15 display signals.

The display signals are signals applied on the first electrode and the second electrode. In some embodiments, the display signals are driving signals for displaying an image at the display stage.

For example, in the touch display substrate in FIG. 2, the first touch-control electrode 29 is connected to the conductive pattern 26. For example, the conductive pattern 26 is a gate electrode of a switching transistor that is arranged in the touch display substrate and is configured to drive a storage capacitor. At the display stage, scanning signals for driving the storage capacitor are applied to the first touch-control electrode 29 and the conductive pattern 26. At the touch recognition stage, touch-control signals are applied to the first touch-control electrode 29 and the conductive pattern 26; at this time, the first touch-control electrode realizes a touch recognition function, and a display function may not be affected since the touch recognition stage is instantaneous.

In some embodiments, the second touch-control electrode and the second electrode are connected to an identical signal line, so the second touch-control electrode and the second electrode are driven in a time-division manner.

At the display stage, cathode signals are applied to the second touch-control electrode 29 and the second electrode; at this time, the first touch-control electrode 29 is not used for touch detection and the second electrode operates normally to drive image displaying. At the touch recognition stage, touch-control signals are applied to the first touch-control electrode 29 and the second electrode; at this time, the second touch-control electrode 29 is configured to detect a touch operation, and a display function may not be affected since the touch recognition stage is instantaneous.

1. A touch display substrate, comprising: a base substrate, a first touch-control electrode, a second touch-control electrode and a separation pattern;
wherein the base substrate comprises a plurality of pixel units, each pixel unit comprises a first electrode and a second electrode insulated from each other; the separation pattern is arranged between two adjacent pixel units and is made of an insulating material; the first touch-control electrode is arranged at a side of the separation pattern close to the base substrate; the second touch-control electrode is arranged at a side of the separation pattern away from the base substrate; the first touch-control electrode and the first electrode are arranged in a same layer; and the second touch-control electrode and the second electrode are arranged in a same layer.

2. The touch display substrate according to claim 1, wherein a distance between the first electrode and the first touch-control electrode adjacent to each other ranges from 5 μm to 15 μm.

3. The touch display substrate according to claim 1, wherein the first electrode and the first touch-control electrode are made of an identical material.

4. The touch display substrate according to claim 1, wherein the second electrode and the second touch-control electrode are made of an identical material.

5. The touch display substrate according to claim 1, wherein the first electrode and the first touch-control electrode are made of an identical material, and the second electrode and the second touch-control electrode arc made of an identical material.

6. The touch display substrate according to claim 1, further comprising: a thin film transistor formed on the base substrate, wherein a drain electrode of the thin film transistor is connected to the first electrode.

7. The touch display substrate according to claim 1, further comprising: an organic light-emitting layer arranged between, the first electrode and the second electrode.

8. The touch display substrate according to claim 1, wherein the separation pattern is a black matrix or a pixel defining layer.

9. A manufacturing method for a touch display substrate, comprising:
forming a plurality of pixel units on a base substrate, wherein each pixel unit comprises, a first electrode and a second electrode insulated from each other;
forming a separation pattern between two adjacent pixel units, wherein the separation pattern is made of an insulating material;
forming a first touch-control electrode on a side of the separation pattern close to the base substrate; and
forming a second touch-control electrode on a side of the separation pattern away from the base substrate;
wherein the first touch-control electrode and the first electrode are arranged in a same layer, and the second touch-control electrode and the second electrode are arranged in a same layer.

10. The manufacturing method according to claim 9, further comprising:
forming a conductive pattern on the base substrate before forming the plurality of pixel units on the base substrate;
forming, a first insulating layer covering the conductive pattern; and
forming a first via-hole in the first insulating layer to expose the conductive pattern;
wherein the forming the plurality of pixel units on the base substrate and the forming the first touch-control electrode on the side of the separation pattern close to the base substrate comprise;
forming the first electrode and the first touch-control electrode on the first insulating layer through one patterning process, wherein the first touch control elect rod connected to the conductive pattern via the first via-hole;
wherein the manufacturing method further comprising
forming a second insulating layer covering the first electrode and the first touch-control electrode, after forming the first electrode and the lust touch-control electrode on the first insulating layer, wherein the second insulating layer comprises a second via-hole through which the first electrode exposes; and
forming an organic light-emitting layer, wherein the organic light-emitting layer is connected to the first electrode via the second via-hole, and an orthographic projection of the separation pattern onto the base substrate at least covers an orthographic projection of the first touch-control electrode onto the base substrate; and
wherein the forming the plurality of pixel units on the base substrate and the forming the second touch-control electrode on the side of the separation pattern away from the base substrate comprises;
forming the second electrode and the second touch-control electrode through one patterning process, wherein an orthographic projection of the second electrode onto the base substrate is within an orthographic projection of the first electrode onto the base substrate, and an orthographic projection of the second touch-control electrode onto the base substrate is within the orthographic projection of the first touch-control electrode onto the base substrate.

11. A touch display device, comprising the touch display substrate according to claim 1.

12. A driving method, applied to the touch display device according to claim 11, comprising:
applying, at a display stage, display signals tor displaying an image to the first electrode and the second electrode of each pixel unit respectively; and
applying, at a touch recognition stage, touch-control signals for recognizing a touch operation to the first touch-control electrode and the second touch-control electrode respectively.

13. The touch display substrate according to claim 5, further comprising; a thin film transistor formed on the base substrate, wherein a drain electrode of the thin film transistor is connected to the first electrode.

14. The touch display substrate according to claim 5, further comprising; an organic light-emitting layer arranged between the first electrode and the second electrode.

15. The touch display substrate according to claim 5, wherein the separation pattern is a black matrix or a pixel defining layer.

16. The touch display device according to claim 11 wherein a distance between the first electrode and the first touch-control electrode adjacent to each other ranges from 5 μm to 15 μm.

17. The touch display device according to claim 11, wherein the first electrode and the first touch-control electrode are made of an identical material, and the second electrode and the second touch-control electrode are made of an identical material.

18. The touch display device according to claim 11, wherein the touch display substrate further comprises a thin film transistor formed on the base substrate, wherein a drain electrode of the thin film transistor is connected to the first electrode.

19. The touch display device according to claim 11, wherein the touch display substrate further comprises an organic light-emitting layer arranged between the first electrode and the second electrode.

20. The touch display device according, to claim 11, wherein the separation pattern is a black matrix or a pixel defining layer.
